(19) United States
(12) Patent Application Publication
(10) Pub. No.: US 2026/0123542 A1
(43) Pub. Date: Apr. 30, 2026

(54) SEMICONDUCTOR PACKAGING METHOD AND SEMICONDUCTOR PACKAGE

(71) Applicant: WUHAN XINXIN SEMICONDUCTOR MANUFACTURING CO., LTD., Wuhan (CN)

(72) Inventors: Shengjin SONG, Wuhan (CN); Sheng HU, Wuhan (CN)

(21) Appl. No.: 19/262,640

(22) Filed: Jul. 8, 2025

(30) Foreign Application Priority Data
Oct. 29, 2024 (CN) 202411524027.0

(51) Int. Cl. H01L 25/16; H01L 21/56; H01L 23/00; H01L 23/24; H01L 23/48; H10D 88/00

(52) U.S. Cl. CPC H10W 90/00; H10D 88/01; H10W 20/20; H10W 74/01; H10W 76/47; H10W 90/28; H10W 90/792

(57) ABSTRACT

The present invention provides a semiconductor packaging method and a semiconductor package, in which a second semiconductor structure and a third semiconductor structure are bonded to a first semiconductor structure so as to be adjacent to each other, with a gap being left therebetween, and a fluidic insulating layer is then filled in the gap. By virtue of the fluidity, the insulating layer, as formed, has a flat surface, which can avoid the issue of significant post-bonding warpage and/or stress non-uniformity and allows the resulting semiconductor package to have improved quality and reliability.

### CROSS-REFERENCES TO RELATED APPLICATION

This application claims the priority of Chinese patent application number 202411524027.0, filed on Oct. 29, 2024, the entire contents of which are incorporated herein by reference.

### TECHNICAL FIELD

The present invention relates to the field of semiconductor manufacturing technology and, in particular, to a semiconductor packaging method and a semiconductor package.

### BACKGROUND

As the integrated circuit industry steps into the post-Moore's law era, chips are increasingly shrinking in both critical dimension and size, motivating the emergence of some new integration and packaging methods, such as solderless copper-to-copper bonding and hybrid bonding, which can result in great increases in integration density. Hybrid bonding is a technique capable of simultaneously bonding metal electrodes and insulating dielectric layers of wafers/chips. Due to use of micro-bumps being dispensed with, hybrid bonding enables interconnection at an even smaller distance of 10 μm or less. Therefore, hybrid bonding can be used to provide high-density integration and is considered indispensable for 3D packaging.

Depending on what are to be bonded, hybrid bonding may involve wafer-to-wafer bonding (W2W), die-to-die bonding (D2D) and/or die-to-wafer bonding (D2W).

D2W bonding has evolved from bonding of a single die to a wafer to bonding of multiple dies to a wafer, and the latter can result in semiconductor packages with even higher performance. However, bonding of more dies to a wafer may lead to severer warpage and stress issues with the wafer after bonding.

### SUMMARY

It is an object of the present invention to provide semiconductor packaging method and a semiconductor package, which overcome the problem that conventional bonding of more dies to a wafer possibly leads to more significant warpage of the wafer and/or a more non-uniform stress distribution across it after bonding.

To this end, the present invention provides a semiconductor packaging method including:
providing a first semiconductor structure, a second semiconductor structure and a third semiconductor structure;
bonding the second semiconductor structure and the third semiconductor structure to the first semiconductor structure, the second semiconductor structure and the third semiconductor structure are adjacent to each other, with a gap being left between the second semiconductor structure and the third semiconductor structure;
forming an insulating layer, which at least fills the gap and is fluidic; and
curing the insulating layer.

Optionally, in the semiconductor packaging method, the first semiconductor structure may have a first surface and an opposing second surface, and the second semiconductor structure and the third semiconductor structure are bonded to the second surface of the semiconductor structure.

Optionally, in the semiconductor packaging method, the first semiconductor structure may include a stack of multiple wafers, wherein the second semiconductor structure and/or the third semiconductor structure each includes a stack of multiple dies and has a thickness between 10 μm and 400 μm.

Optionally, in the semiconductor packaging method, the first semiconductor structure may include five wafers, the five wafers are successively bonded to a first carrier, after each wafer is bonded, through via holes are formed therein, and wherein each of the second semiconductor structure and/or the third semiconductor structure may include four dies, after each die in the second semiconductor structure and/or the third semiconductor structure is bonded, through via holes are formed therein.

Optionally, in the semiconductor packaging method, the through via holes in the second semiconductor structure and/or the third semiconductor structure may be aligned with and brought into communication with the respective through via holes in the first semiconductor structure.

Optionally, in the semiconductor packaging method, the cured insulating layer may have a first coefficient of thermal expansion, the second semiconductor structure may have a second coefficient of thermal expansion, the third semiconductor structure may have a third coefficient of thermal expansion, wherein a difference between the first and second coefficients of thermal expansion and a difference between the first and third coefficients of thermal expansion are both less than or equal to 10% of the lowest one of the first, second and third coefficients of thermal expansion.

Optionally, in the semiconductor packaging method, the formed insulating layer may include a suspension consisting of a first material and a second material, wherein the first material is a liquid and the second material is a solid; and a maximum particle diameter of the second material is less than or equal to ⅓ of a width of the gap.

Optionally, the semiconductor packaging method may further include, after the insulating layer is cured,
polishing the cured insulating layer until surface(s) of the second semiconductor structure and/or the third semiconductor structure is/are exposed.

Optionally, the semiconductor packaging method may further include, before the second semiconductor structure and the third semiconductor structure are bonded to the first semiconductor structure, forming pads on the first surface, wherein the pads are covered by a dielectric layer.

Optionally, in the semiconductor packaging method, the second semiconductor structure and the third semiconductor structure may be bonded to the first semiconductor structure in the form of an array, the bonding comprises hybrid bonding, fusion bonding or micro-bump bonding.

Optionally, in the semiconductor packaging method, the gap may have a height between 10 μm and 400 μm.

The present invention also provides a semiconductor package including: a first semiconductor structure; a second semiconductor structure and a third semiconductor structure, the second semiconductor structure and the third semiconductor structure are bonded to the first semiconductor structure, the second semiconductor structure and the third semiconductor structure are adjacent to each other, with a gap being left between the second semiconductor structure and the third semiconductor structure; and an insulating layer, which at least fills the gap.

Optionally, in the semiconductor package, the first semiconductor structure may have a first surface and an opposing second surface, wherein pads are formed on the first surface and encapsulated by a dielectric layer, and the second semiconductor structure and the third semiconductor structure are bonded to the second surface of the first semiconductor structure.

Optionally, in the semiconductor package, the first semiconductor structure may include a stack of multiple wafers, wherein the second semiconductor structure and/or the third semiconductor structure each includes a stack of multiple dies and has a thickness between 10 μm and 400 μm.

Optionally, in the semiconductor package, the first semiconductor structure may include five wafers, the five wafers are successively bonded to a first carrier, after each wafer is bonded, through via holes are formed therein, wherein each of the second semiconductor structure and/or the third semiconductor structure includes four dies, after each die in the second semiconductor structure and/or the third semiconductor structure is bonded, through via holes are formed therein.

Optionally, in the semiconductor package, the through via holes in the second semiconductor structure and/or the third semiconductor structure may be aligned with and brought into communication with the respective through via holes in the first semiconductor structure.

Optionally, in the semiconductor package, the insulating layer may have a first coefficient of thermal expansion, the second semiconductor structure may have a second coefficient of thermal expansion, and the third semiconductor structure may have a third coefficient of thermal expansion, wherein a difference between the first and second coefficients of thermal expansion and a difference between the first and third coefficients of thermal expansion are both less than or equal to 10% of the lowest one of the first, second and third coefficients of thermal expansion.

Optionally, in the semiconductor package, the formed insulating layer comprises a suspension consisting of a first material and a second material; the first material is a liquid and the second material is a solid; and a maximum particle diameter of the second material is less than or equal to ⅓ of a width of the gap.

Optionally, the semiconductor package may further include pads formed on the first surface, wherein the pads are covered by a dielectric layer.

Optionally, in the semiconductor package, the gap may have a height between 10 μm and 400 μm.

The present inventors have found from studies that bonding of a stack of more dies to a wafer is associated with more significant post-bonding warpage and/or stress non-uniformity of the wafer because the greater number of dies leads to a significantly increased overall thickness. As a consequence of this greater thickness, a film or layer deposited on the dies after they are bonded to the wafer typically has very poor surface uniformity, which leads to significant warpage of the whole wafer and a highly non-uniform stress distribution across it.

In view of this, the present invention provides a semiconductor packaging method and a semiconductor package, in which a second semiconductor structure and a third semiconductor structure are bonded to a first semiconductor structure so as to be adjacent to each other, with a gap being left therebetween, and a fluidic insulating layer is then filled in the gap. By virtue of the fluidity, the insulating layer, as formed, has a flat surface, which can avoid the issue of significant post-bonding warpage and/or stress non-uniformity and allows the resulting semiconductor package to have improved quality and reliability.

### BRIEF DESCRIPTION OF THE DRAWINGS

FIG. 1 is a schematic partial cross-sectional view of a structure resulting from bonding of a first semiconductor structure, a second semiconductor structure and a third semiconductor structure according to an embodiment of the present invention.

FIG. 2 is a schematic partial cross-sectional view of a structure resulting from curing of an insulating layer according to an embodiment of the present invention.

FIG. 3 is a schematic partial cross-sectional view of a structure resulting from polishing of an insulating layer according to an embodiment of the present invention.

FIG. 4 is a schematic partial cross-sectional view of a structure resulting from bonding of a second carrier according to an embodiment of the present invention.

FIG. 5 is a schematic partial cross-sectional view of a structure resulting from removal of a first carrier according to an embodiment of the present invention.

FIG. 6 is a schematic partial cross-sectional view of a structure resulting from exposure of pads according to an embodiment of the present invention.

In these figures,
100 denotes a first semiconductor structure; 101, a wafer; 1000, a solder pad; 102, a dielectric layer; 200, a second semiconductor structure; 201, a die; 210, a third semiconductor structure; 300, a first carrier; 400, an insulating layer; 500, a second carrier; and H, a gap.

### DETAILED DESCRIPTION

Semiconductor packaging methods and semiconductor packages proposed herein will be described in greater detail below with reference to the accompanying drawings, which illustrate particular embodiments thereof. From the following description, advantages and features of the present invention will be more apparent. Note that the figure is provided in a very simplified form not necessarily drawn to exact scale for the only purpose of helping to explain the disclosed embodiments in a more convenient and clearer way.

The terminology used herein is for the purpose of describing particular embodiments only and is not intended to be limiting of the invention. Unless defined otherwise herein, all technical and scientific terms used herein have the same meaning as commonly understood by one of ordinary skill in the art to which the invention belongs. As used herein and in the appended claims, the terms “first,” “second,” and the like do not denote any order, quantity, or importance, but rather are used to distinguish one element from another. Likewise, the terms “a” and “an” do not denote a limitation of quantity, but rather denote the presence of at least one of the referenced item. The terms “plurality” or “several” means two or more than two. Unless defined otherwise herein, the terms “upper”, “overlying”, “lower”, “underlying” and/or the like are merely for ease of description, and should not be construed as being limited to a particular position, or to a particular spatial orientation. The use of “including” or “comprising” or the like herein is meant to encompass the elements or items listed thereafter and equivalents thereof but do not preclude the presence of other elements or items. The terms “connected”, “coupled” or the like are not restricted to physical or mechanical connections or couplings, and can include electrical connections or couplings, whether direct or indirect. As used herein and in the appended claims, the singular forms “a”, “an”, and the” are intended to include the plural forms as well, unless the context clearly indicates otherwise. It will be also understood that, as used herein, the term “and/or” includes any and all combinations of one or more of the associated listed items.

Bonding of more dies to a wafer may lead to severer warpage and stress issues with the wafer after bonding. To overcome this, the present inventors have conducted in-depth studies and found that a stack of more dies has a significantly increased overall thickness, which typically leads to very poor surface uniformity of a film or layer deposited on the dies after they are bonded to a wafer. It is just such inferior surface uniformity that accounts for significant warpage of the whole wafer and a highly non-uniform stress distribution across it. Furthermore, due to the poor surface uniformity of the deposited film or layer, a force applied to the wafer in a subsequent chemical mechanical polishing (CMP) process would also be highly non-uniform, making this planarization process likely to exacerbate rather than mitigate the warpage and stress non-uniformity of the wafer.

In view of this, the inventors provide semiconductor packaging method and a semiconductor package, in which a second semiconductor structure and a third semiconductor structure are bonded to a first semiconductor structure so as to be adjacent to each other, with a gap being left therebetween, and a fluidic insulating layer is then filled in the gap. By virtue of the fluidity, the insulating layer, as formed, has a flat surface, which can avoid the issue of significant post-bonding warpage and/or stress non-uniformity and allows the resulting semiconductor package to have improved quality and reliability.

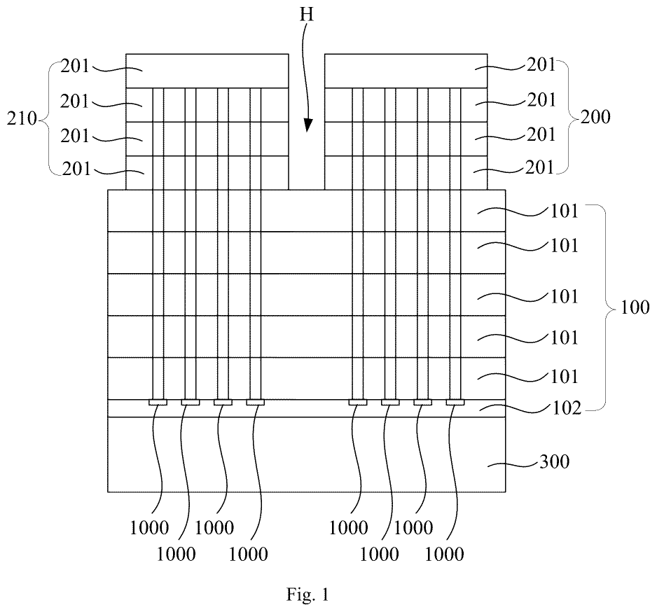

Particular reference is now made to FIGS. 1 to 6, which show schematic partial cross-sectional views of structures resulting from steps in a semiconductor packaging method according to an embodiment of the present invention.

As shown in FIG. 1, a first semiconductor structure 100, a second semiconductor structure 200 and a third semiconductor structure 210 are provided, and the second semiconductor structure 200 and the third semiconductor structure 210 are then bonded to the first semiconductor structure 100 so as to be adjacent to each other, with a gap H being left therebetween. The second semiconductor structure 200 and the third semiconductor structure 210 may be bonded to the first semiconductor structure 100 in the form of an array. The first semiconductor structure 100 may be sized larger than both the second semiconductor structure 200 and the third semiconductor structure 210. In other embodiments, the sizes of the first semiconductor structure 100, the second semiconductor structure 200 and the third semiconductor structure 210 may be properly determined, as needed. Each of the first semiconductor structure 100, the second semiconductor structure 200 and the third semiconductor structure 210 may be made of a semiconductor material, a non-semiconductor material or a combination thereof. As used herein, the term “bonding” may include, but is not limited to, hybrid bonding, fusion bonding and micro-bump bonding.

In one embodiment, the first semiconductor structure 100 may be, but is not limited to being, a single wafer or a stack of multiple wafers. Each of the second semiconductor structure 200 and the third semiconductor structure 210 may be, but is not limited to being, a single die or a stack of multiple dies. Herein, the term “multiple” is used in the sense of “at least two”. The second semiconductor structure 200 and the third semiconductor structure 210 may be of the same material or thickness, or not. In FIG. 1, each of the second semiconductor structure 200 and the third semiconductor structure 210 is schematically illustrated as a stack of multiple dies, for example, four dies 201. That is, each of the second semiconductor structure 200 and the third semiconductor structure 210 includes four dies 201, in which adjacent dies 201 are joined together by bonding, for example, by hybrid bonding. In FIG. 1, the first semiconductor structure 100 is schematically illustrated as a stack of multiple wafers, for example, five wafers 101. That is, the first semiconductor structure 100 includes five wafers 101, in which adjacent wafers 101 are joined together by bonding, for example, by hybrid bonding. It should be noted that the present application is not limited to any particular number of wafers in the wafer stack or to any particular number of dies in each die stack.

In embodiments of the present application, before the second semiconductor structure 200 and the third semiconductor structure 210 are bonded to the first semiconductor structure 100, the first semiconductor structure 100 is bonded to a first carrier 300 in order to facilitate the performance of the subsequent processes. In the embodiment of FIG. 1, the five wafers 101 may be successively bonded to the first carrier 300, thus obtaining the first semiconductor structure 100.

Additionally, in embodiments of the present application, the first semiconductor structure 100 has a first surface and an opposing second surface, with pads 1000 being formed on the first surface, and is bonded to the first carrier 300 at the first surface. The second semiconductor structure 200 and the third semiconductor structure 210 are both bonded to the second surface of the first semiconductor structure 100. For example, the first semiconductor structure 100 may include a first wafer 101, a second wafer 101, a third wafer 101, a fourth wafer 101 and a fifth wafer 101, which are sequentially bonded together in this order, and the second semiconductor structure 200 and the third semiconductor structure 210 are both bonded to the fifth wafer 101. In one embodiment, the pads 1000 are formed on a surface of the first wafer 101 away from the second wafer 101 and covered by a dielectric layer 102, which encapsulates the pads 1000 to provide protection thereto and is bonded at a side thereof away from the pads 1000 to the first carrier 300. The second wafer 101, the third wafer 101, the fourth wafer 101 and the fifth wafer 101 are sequentially bonded to a side of the first wafer 101 away from the first carrier 300. In another embodiment, after the second wafer 101, the third wafer 101, the fourth wafer 101 and the fifth wafer 101 are sequentially bonded to the first wafer 101, the pads 1000 are formed on the surface of the first wafer 101 away from the second wafer 101, and the dielectric layer 102 is formed on the pads 1000 so as to encapsulate the pads 1000 to provide protection thereto and bonded to the first carrier 300 at the side away from the pads 1000.

In embodiments of the present application, through silicon vias (TSVs) are formed as signal connections between the wafers 101 in the first semiconductor structure 100, between the dies 201 in each of the second semiconductor structure 200 and the third semiconductor structure 210, between the first semiconductor structure 100 and the second semiconductor structure 200 and between the first semiconductor structure 100 and the third semiconductor structure 210. In particular, after each wafer 101 is bonded, through via holes may be formed therein. Similarly, after each die 201 in the second semiconductor structure 200 and the third semiconductor structure 210 is bonded, through via holes may be formed therein. The second semiconductor structure 200 and the third semiconductor structure 210 may be then bonded to the first semiconductor structure 100 so that the through via holes in the second semiconductor structure 200 and the third semiconductor structure 210 are aligned with and brought into communication with the respective through via holes in the first semiconductor structure 100.

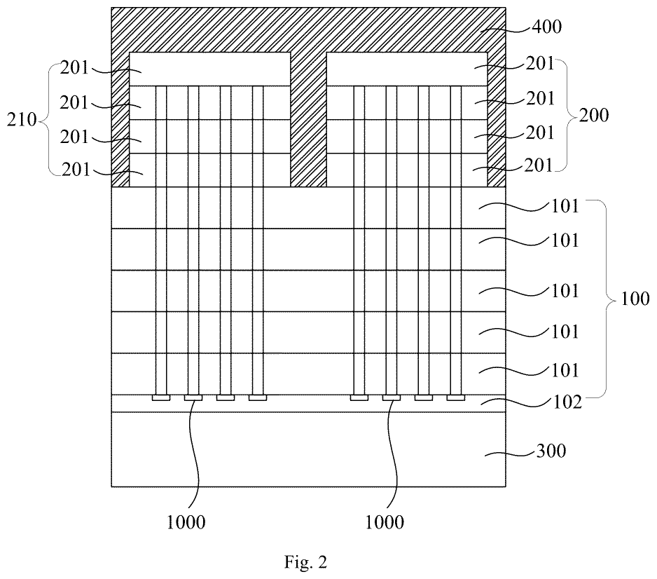

Referring to FIG. 2, an insulating layer 400 is then formed, which fills the gap H. In embodiments of the present application, the insulating layer 400 is fluidic and covers the second semiconductor structure 200, the third semiconductor structure 210 and the first semiconductor structure 100. That is, the insulating layer 400 encapsulates the second semiconductor structure 200 and the third semiconductor structure 210 and covers portions of the first semiconductor structure 100 not covered by the second semiconductor structure 200 and the third semiconductor structure 210. In embodiments of the present application, the second semiconductor structure 200 and/or the third semiconductor structure 210 may have a thickness lying between 10 μm and 400 μm. That is, the gap H may have a height between 10 μm and 400 μm. Preferably, the thickness of the second semiconductor structure 200 and/or the third semiconductor structure 210 may lie between 25 μm and 160 μm. That is, there may be a height difference of 25 μm to 160 μm, or of 10 μm to 400 μm, between top surface(s) of the second semiconductor structure 200 and/or the third semiconductor structure 210 and a top surface of the first semiconductor structure 100. In embodiments of the present application, during the formation of the insulating layer 400, it is fluidic and thereby accommodates any height difference, resulting in a flat surface, which avoids the issue of significant post-D2W bonding warpage and/or stress non-uniformity of the wafer that may arise from a large number of dies being stacked.

The height difference between the top surfaces of the second semiconductor structure 200 and the first semiconductor structure 100 may be equal to the height difference between the top surfaces of the third semiconductor structure 210 and the first semiconductor structure 100, or not. By virtue of the fluidity, the insulating layer 400 can not only fill the gap H in a desirable way, but can also accommodate a height difference between the second semiconductor structure 200 and the third semiconductor structure 210, resulting in a flat surface and hence a uniform stress distribution.

In embodiments of the present application, the insulating layer 400 includes a suspension consisting of a first material and a second material. The first material is a liquid. For example, the first material may be a gel-like liquid. The second material is a solid. Preferably, a maximum particle diameter of the second material is less than or equal to ⅓ of a width of the gap H, measured as a distance between the second semiconductor structure 200 and the third semiconductor structure 210. This facilitates the filling of the gap H by the insulating layer 400 and enables the filled insulating layer 400 to be flat.

For example, the insulating layer 400 may be made of an epoxy resin, an organic polymer, or a polymer with or without silica-based filler or glass filler being added thereto. Preferably, the insulating layer 400 is formed using a mold, for example, provided as a box, in which the bonded first, second and third semiconductor structures 100, 200, 210 can be placed, and which can limit the fluidic material of the insulating layer 400 during its formation, thereby facilitating the formation.

With continued reference to FIG. 2, the insulating layer 400 is cured. For example, it may be cured by applying heat to it, or otherwise, for example, by irradiating it with light. Preferably, the cured insulating layer 400 has a first coefficient of thermal expansion, the second semiconductor structure 200 has a second coefficient of thermal expansion, and the third semiconductor structure 210 has a third coefficient of thermal expansion. The coefficient of thermal expansion of the second semiconductor structure 200 may be equal to that of the third semiconductor structure 210, or not. A difference between the first and second coefficients of thermal expansion and a difference between the first and third coefficients of thermal expansion are both less than or equal to 10% of the lowest one of the first, second and third coefficients of thermal expansion. That is, the both differences are both less than or equal to 10% of the first coefficient of thermal expansion, less than or equal to 10% of the second coefficient of thermal expansion, and less than or equal to 10% of the third coefficient of thermal expansion. For example, the second coefficient of thermal expansion may be 20E-6/K, and the first coefficient of thermal expansion may lie between 18.2E-6/K and 22E-6/K. This can additionally ensure flatness of the cured insulating layer 400 between the second semiconductor structure 200 and the third semiconductor structure 210 and reliable curing thereof.

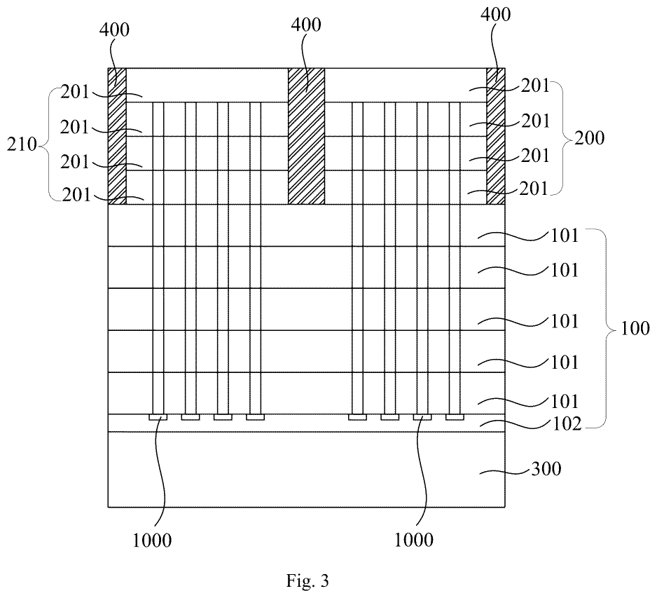

Next, as shown in FIG. 3, the cured insulating layer 400 is polished until the surface(s) of the second semiconductor structure 200 and/or the third semiconductor structure 210 is/are exposed. When the second semiconductor structure 200 and the third semiconductor structure 210 have different heights, the polishing process is stopped upon exposure of either of the second semiconductor structure 200 or the third semiconductor structure 210, whichever is higher and exposed first. This can facilitate heat dissipation of the second semiconductor structure 200 and/or the third semiconductor structure 210.

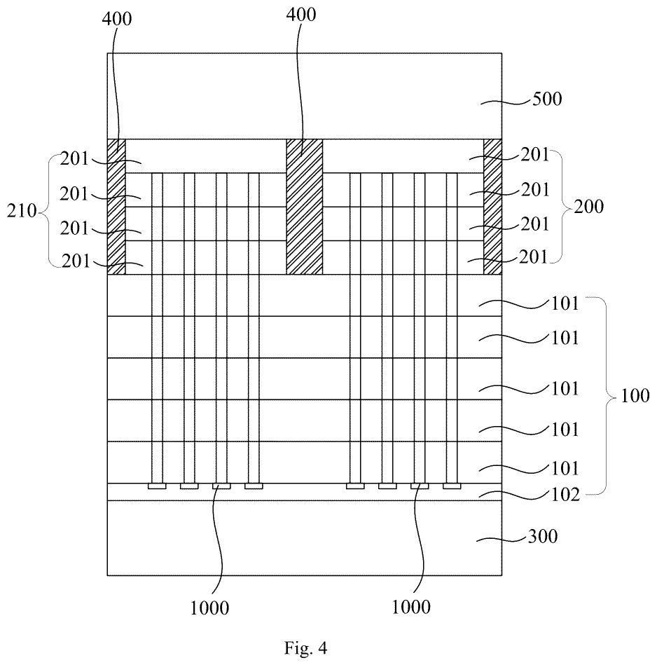

With additional reference to FIG. 4, a second carrier 500 is bonded to the second semiconductor structure 200, the third semiconductor structure 210 and the insulating layer 400. The second carrier 500 may be a semiconductor carrier, such as a silicon wafer. This can additionally facilitate heat dissipation of the second semiconductor structure 200 and/or the third semiconductor structure 210, resulting in improvements in quality and reliability of the semiconductor package being fabricated.

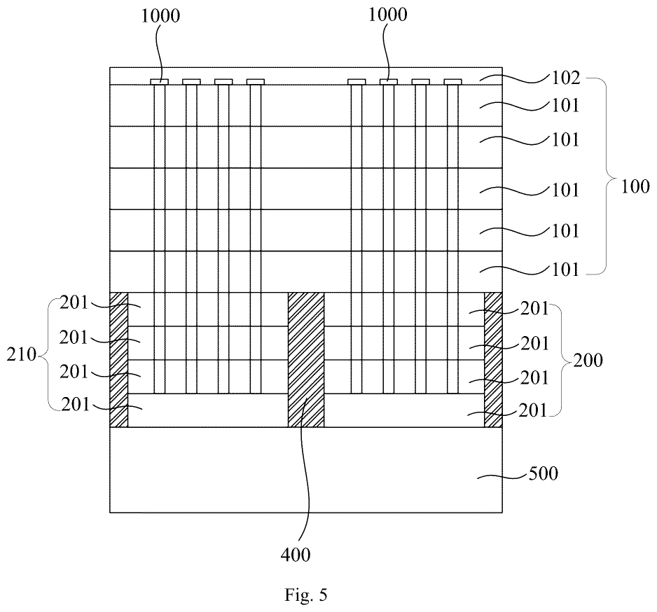

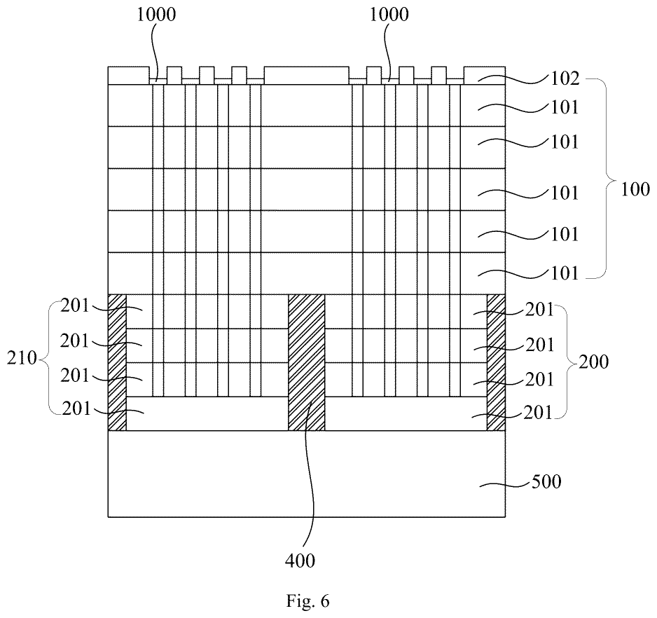

With additional reference to FIGS. 5 and 6, the first carrier 300 is removed, for example, by a debonding process. The dielectric layer 102 is then partially removed, exposing the pads 1000. In particular embodiments of the present application, the dielectric layer 102 residing on the pads 1000 may be etched away to expose surfaces of the pads 1000, allowing external connection of the pads 1000 for signal communication.

Embodiments of the present application also provide a corresponding semiconductor package obtainable according to the semiconductor packaging method as discussed above, which includes: a first semiconductor structure 100; a second semiconductor structure 200 and a third semiconductor structure 210, which are both bonded to the first semiconductor structure 100, with a gap H being left therebetween; and an insulating layer 400, which at least fills gap H. In embodiments of the present application, the insulating layer 400 covers surfaces of the second semiconductor structure 200, the third semiconductor structure 210 and the first semiconductor structure 100. The insulating layer 400 has a first coefficient of thermal expansion, the second semiconductor structure 200 has a second coefficient of thermal expansion, and the third semiconductor structure 210 has a third coefficient of thermal expansion. A difference between the first and second coefficients of thermal expansion and a difference between the first and third coefficients of thermal expansion are both less than or equal to 10% of the lowest one of the first, second and third coefficients of thermal expansion. That is, both differences are less than or equal to 10% of the first coefficient of thermal expansion, less than or equal to 10% of the second coefficient of thermal expansion, and less than or equal to 10% of the third coefficient of thermal expansion.

In the semiconductor packaging method and the semiconductor package of the present invention, second and third semiconductor structures are bonded to a first semiconductor structure so as to be adjacent to each other, with a gap being left therebetween, and a fluidic insulating layer is then filled in the gap. By virtue of the fluidity, the insulating layer, as formed, has a flat surface, which can avoid the issue of significant post-bonding warpage and/or stress non-uniformity and allows the resulting semiconductor package to have improved quality and reliability.

As used herein, any reference to “one embodiment” or “some embodiments” means that a particular feature, structure, or characteristic described in connection with the embodiment is included in at least one embodiment or at least some embodiments disclosed herein. Therefore, the appearances of the phrase “in one embodiment” or “in some embodiments” in various places in the specification are not necessarily all referring to the same one or some embodiments. Further, in one or more embodiments, features, structures or characteristics may be combined in any suitable combination and/or sub-combination.

While a few particular embodiment of the present application have been described in detail by way of examples, those skilled in the art will understand that the foregoing examples are provided for illustration only rather than any limitation on the scope of the application. The various embodiments disclosed herein can be combined in any combination, without departing from the spirit and scope of the application. Those skilled in the art will also understand that various modifications can be made to the embodiments, without departing from the scope and spirit of the application. The scope of the application is defined by the appended claims.

1. A semiconductor packaging method, comprising:
providing a first semiconductor structure, a second semiconductor structure and a third semiconductor structure;
bonding the second semiconductor structure and the third semiconductor structure to the first semiconductor structure, the second semiconductor structure and the third semiconductor structure are adjacent to each other, with a gap being left between the second semiconductor structure and the third semiconductor structure;
forming an insulating layer, which at least fills the gap and is fluidic; and
curing the insulating layer.

2. The semiconductor packaging method of claim 1, wherein the first semiconductor structure has a first surface and a second surface opposite to the first surface; and the second semiconductor structure and the third semiconductor structure are bonded to the second surface of the semiconductor structure.

3. The semiconductor packaging method of claim 1, wherein the first semiconductor structure comprises a stack of multiple wafers, the second semiconductor structure and/or the third semiconductor structure each comprises a stack of multiple dies, and the second semiconductor structure and/or the third semiconductor structure each has a thickness between 10 μm and 400 μm.

4. The semiconductor packaging method of claim 3, wherein the first semiconductor structure includes five wafers, the five wafers are successively bonded to a first carrier, after each wafer is bonded, through via holes are formed therein, and wherein each of the second semiconductor structure and/or the third semiconductor structure includes four dies, after each die in the second semiconductor structure and/or the third semiconductor structure is bonded, through via holes are formed therein.

5. The semiconductor packaging method of claim 4, wherein the through via holes in the second semiconductor structure and/or the third semiconductor structure are aligned with and brought into communication with the respective through via holes in the first semiconductor structure.

6. The semiconductor packaging method of claim 1, wherein the cured insulating layer has a first coefficient of thermal expansion, the second semiconductor structure has a second coefficient of thermal expansion, and the third semiconductor structure has a third coefficient of thermal expansion; and a difference between the first coefficient of thermal expansion and the second coefficient of thermal expansion and a difference between the first coefficient of thermal expansion and the third coefficient of thermal expansion are both less than or equal to 10% of the lowest one of the first coefficient of thermal expansion, the second coefficient of thermal expansion and the third coefficient of thermal expansion.

7. The semiconductor packaging method of claim 1, wherein the formed insulating layer comprises a suspension consisting of a first material and a second material; the first material is a liquid and the second material is a solid; and a maximum particle diameter of the second material is less than or equal to ⅓ of a width of the gap.

8. The semiconductor packaging method of claim 1, further comprising, after the insulating layer is cured,
polishing the cured insulating layer until surface(s) of the second semiconductor structure and/or the third semiconductor structure is/are exposed.

9. The semiconductor packaging method of claim 2, further comprising, before the second semiconductor structure and the third semiconductor structure are bonded to the first semiconductor structure,
forming pads on the first surface, wherein the pads are covered by a dielectric layer.

10. The semiconductor packaging method of claim 1, wherein the second semiconductor structure and the third semiconductor structure are bonded to the first semiconductor structure in the form of an array, the bonding comprises hybrid bonding, fusion bonding or micro-bump bonding.

11. The semiconductor packaging method of claim 1, wherein the gap has a height between 10 μm and 400 μm.

12. A semiconductor package, comprising: a first semiconductor structure; a second semiconductor structure and a third semiconductor structure, the second semiconductor structure and the third semiconductor structure are bonded to the first semiconductor structure, the second semiconductor structure and the third semiconductor structure are adjacent to each other, with a gap being left between the second semiconductor structure and the third semiconductor structure; and an insulating layer, which at least fills the gap.

13. The semiconductor package of claim 12, wherein the first semiconductor structure has a first surface and a second surface opposite to the first surface; and the second semiconductor structure and the third semiconductor structure are bonded to the second surface of the first semiconductor structure.

14. The semiconductor package of claim 12, wherein the first semiconductor structure comprises a stack of multiple wafers, and the second semiconductor structure and/or the third semiconductor structure each comprises a stack of multiple dies, and the second semiconductor structure and/or the third semiconductor structure each has a thickness between 10 μm and 400 μm.

15. The semiconductor package of claim 14, wherein the first semiconductor structure includes five wafers, the five wafers are successively bonded to a first carrier, after each wafer is bonded, through via holes are formed therein, wherein each of the second semiconductor structure and/or the third semiconductor structure includes four dies, after each die in the second semiconductor structure and/or the third semiconductor structure is bonded, through via holes are formed therein.

16. The semiconductor package of claim 15, wherein the through via holes in the second semiconductor structure and/or the third semiconductor structure are aligned with and brought into communication with the respective through via holes in the first semiconductor structure.

17. The semiconductor package of claim 12, wherein the insulating layer has a first coefficient of thermal expansion, the second semiconductor structure has a second coefficient of thermal expansion, and the third semiconductor structure has a third coefficient of thermal expansion; and a difference between the first coefficient of thermal expansion and the second coefficient of thermal expansion and a difference between the first coefficient of thermal expansion and the third coefficient of thermal expansion are both less than or equal to 10% of the lowest one of the first coefficient of thermal expansion, the second coefficient of thermal expansion and the third coefficient of thermal expansion.

18. The semiconductor package of claim 12, wherein the formed insulating layer comprises a suspension consisting of a first material and a second material; the first material is a liquid and the second material is a solid; and a maximum particle diameter of the second material is less than or equal to ⅓ of a width of the gap.

19. The semiconductor package of claim 13, further comprising pads formed on the first surface, wherein the pads are covered by a dielectric layer.

20. The semiconductor package of claim 12, wherein the gap has a height between 10 μm and 400 μm.
